(19) United States
(12) Patent Application Publication
(10) Pub. No.: US 2021/0111535 A1
(43) Pub. Date: Apr. 15, 2021

(54) VERTICAL CAVITY SURFACE EMITTING LASER DEVICE

(71) Applicant: Lextar Electronics Corporation, Hsinchu (TW)

(72) Inventors: Gang-Wei FAN, Hsinchu (TW); Yu-Chen LIN, Hsinchu (TW); Chung-Yu HONG, Hsinchu (TW)

(21) Appl. No.: 16/799,796

(22) Filed: Feb. 24, 2020

(30) Foreign Application Priority Data
Oct. 9, 2019 (CN) 201910954613.1

(51) Int. Cl. H01S 5/042; H01S 5/02; H01S 5/183; H01S 5/34; H01S 5/028

(52) U.S. Cl. CPC H01S 5/04254; H01S 5/0206; H01S 5/18361; H01S 5/04257; H01S 5/34; H01S 5/028; H01S 5/18325

(57) ABSTRACT

A VCSEL device includes a semiconductor substrate; a current conductive layer on the semiconductor substrate; a N-type Bragg reflector layer in contact with the current conductive layer; a P-type Bragg reflector layer above the N-type Bragg reflector layer; an active emitter layer; a current restriction layer, wherein the current restriction layer has a current restriction hole; a metal layer in contact with the semiconductor substrate, the metal layer has a through hole aligned with the current restriction hole; a P-type bonding pad in ohmic contact with the P-type Bragg reflector layer, and a portion of the P-type bonding pad is aligned with the current restriction hole and the through hole; and a N-type bonding pad in ohmic contact with the current conductive layer, and electrically separated from the P-type bonding pad. The P-type bonding pad and the N-type bonding pad are at a same side of the semiconductor substrate.

### CROSS-REFERENCE TO RELATED APPLICATION

This application claims priority to China Application Serial Number 201910954613.1, filed Oct. 9, 2019, which is herein incorporated by reference in its entirety.

### BACKGROUND

### Field of Invention

The present disclosure relates to a vertical cavity surface emitting laser device.

### Description of Related Art

The vertical cavity surface emitting laser device has many advantages in its manufacturing process than the edge-emitting laser device. For example, the vertical cavity surface emitting laser device can be tested and problem-solved in situ during any step of its manufacturing process because of the laser light emitting perpendicularly from a reaction area of the vertical cavity surface emitting laser device.

However, the vertical cavity surface emitting laser device is a high-power light-emitting device. If the light-emitting device is manufactured with a thin thickness, the heat dissipation and reliability issues must be solved.

### SUMMARY

One aspect of the present disclosure is to provide a vertical cavity surface emitting laser (VCSEL) device including a semiconductor substrate having a thickness ranging from 50 microns to 150 microns; a current conductive layer on the semiconductor substrate and having a carrier concentration ranging from 3E18 to 5E18; a N-type Bragg reflector layer in contact with the current conductive layer; a P-type Bragg reflector layer above the N-type Bragg reflector layer; an active emitter layer between the P-type Bragg reflector layer and the N-type Bragg reflector layer; a current restriction layer between the active emitter layer and the P-type Bragg reflector layer, wherein the current restriction layer has a current restriction hole; a metal layer in contact with the semiconductor substrate, wherein the semiconductor substrate is between the N-type Bragg reflector layer and the metal layer, wherein the metal layer has a through hole aligned with the current restriction hole; a P-type bonding pad in ohmic contact with the P-type Bragg reflector layer, and a portion of the P-type bonding pad is aligned with the current restriction hole and the through hole; and a N-type bonding pad in ohmic contact with the current conductive layer, and electrically separated from the P-type bonding pad, wherein the P-type bonding pad and the N-type bonding pad are located at a same side of the semiconductor substrate. Each of the metal layer, the P-type bonding pad and the N-type bonding pad has a thickness ranging from 20 microns to 40 microns so as to achieve a stress relief system.

In one or more embodiments, the semiconductor substrate is located between the metal layer and the P-type, N-type bonding pads.

In one or more embodiments, the active emitter layer includes quantum wells.

In one or more embodiments, the VCSEL device further include an ohmic contact layer between the P-type bonding pad and the P-type Bragg reflector layer.

In one or more embodiments, the VCSEL device further include an ohmic contact layer between the N-type bonding pad and the current conductive layer.

In one or more embodiments, the VCSEL device further include an anti-reflection layer over a surface of the metal layer and the through hole.

In one or more embodiments, the current conductive layer has a thickness ranging from 1.5 microns to 3 microns.

In one or more embodiments, a projection area of the P-type Bragg reflector layer on the semiconductor substrate is smaller than a projection area of the N-type Bragg reflector layer on the semiconductor substrate.

In one or more embodiments, the VCSEL device further include an insulation structure penetrating through the P-type Bragg reflector layer and the active emitter layer.

In one or more embodiments, the VCSEL device further include an insulation structure penetrating through the P-type Bragg reflector layer, the active emitter layer and the N-type Bragg reflector layer.

In summary, the vertical cavity surface emitting laser device of the present invention reduces the thickness of the laser device as a whole by reducing the thickness of the semiconductor substrate down to a range from 50 μm to 150 μm, and the metal layer, the P-type bonding pad and the N-type bonding pad each have a thickness between 20 micrometers and 40 micrometers so as to form a stress relief system, thereby balancing the stress within the layers to prevent warpage.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of a vertical cavity surface emitting laser device in accordance with one embodiment of the present disclosure; and

FIGS. 2-13 illustrate cross-sectional views of a method for manufacturing a vertical cavity surface emitting laser device at various stages in accordance with some embodiments of the present disclosure.

### DETAILED DESCRIPTION

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not be necessarily be drawn to scale, and the identical elements of the embodiments are designated with the same reference numerals.

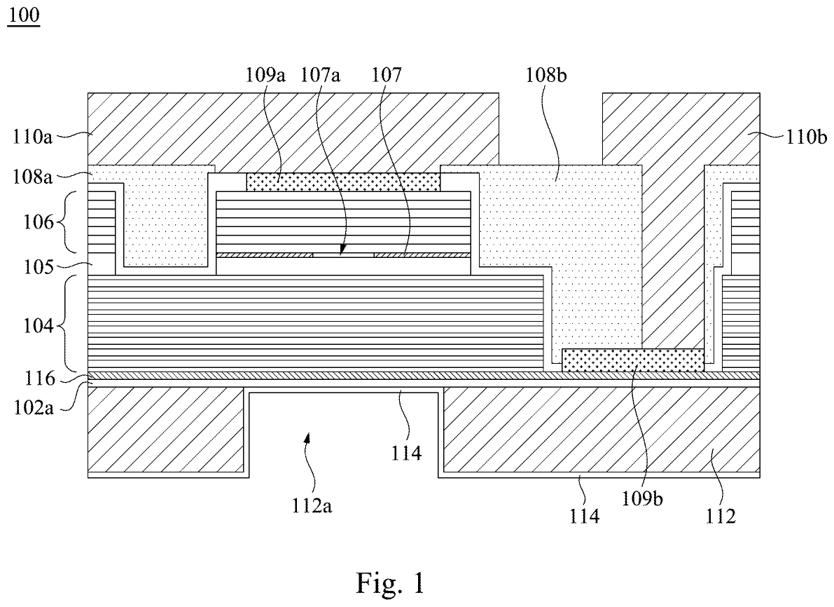

Reference is made to FIG. 1, which illustrates a cross-sectional view of a vertical cavity surface emitting laser device in accordance with one embodiment of the present disclosure. The vertical cavity surface emitting laser device 100 disclosed herein includes a semiconductor substrate 102a, a current conductive layer 116, a N-type Bragg reflector layer 104, a P-type Bragg reflector layer 106, an active emitter layer 105, a current restriction layer 107, a metal layer 112, a P-type bonding pad 110a and a N-type bonding pad 110b. In some embodiments of the present disclosure, the semiconductor substrate 102a is reduced to have a thickness between 50 micrometers and 150 micrometers, thereby reducing the overall thickness of the laser device and improving heat dissipation performance. In some embodiments of the present disclosure, the current conductive layer 116 is located above the semiconductor substrate and in contact with the N-type Bragg reflector layer 104. The current conductive layer 116 has a carrier concentration ranging from 3E18 to 5E18, and serves as a current conductive channel between the N-type bonding pad 110b and the N-type Bragg reflector layer 104. The active emitter layer 105 is located between the P-type Bragg reflector layer 106 and the N-type Bragg reflector layer 104. The current restriction layer 107 is located between the active emitter layer 105 and the P-type Bragg reflector layer 106. The current restriction layer 107 has a current restriction hole 107a allowing electrical currents passing through such that the light emitting area of the active emitter layer 105 is mainly concentrated in the area where the current restriction hole 107a is aligned, thereby meeting the light emitting requirements of the laser device. The metal layer 112 is in contact with the semiconductor substrate 102a, and the semiconductor substrate 102a is located between the N-type Bragg reflector layer 104 and the metal layer 112. The metal layer 112 has a through hole 112a aligned with the current restriction hole 107a to serve as a light emitting hole of the laser device. The P-type bonding pad 110a is in ohmic contact with the P-type Bragg reflector layer 106, and a part of the P-type bonding pad 110a is aligned with the current restriction hole 107a and the through hole 112a. The N-type bonding pad 110b is in ohmic contact with the current conductive layer 116 and is electrically separated from the P-type bonding pad 110a. The P-type bonding pad 110a and the N-type bonding pad 110b are located on a same side of the semiconductor substrate 102a. In some embodiments of the present disclosure, the metal layer 112, P-type bonding pad 110a, and N-type bonding pad 110b each have a thickness between 20 micrometers and 40 micrometers, so as to relatively form a stress relief system, thereby balancing the stress within the layers to prevent warpage. In addition, the metal layer 112, the P-type bonding pad 110a, and the N-type bonding pad 110b each has a thickness greater than 10 micrometers, thereby also increasing the overall heat dissipation efficiency.

In some embodiments of the present disclosure, the metal layer 112 has a thickness greater than 10 microns, thereby increasing thermal conductivity and mechanical strength.

In some embodiments of the present disclosure, the semiconductor substrate 102a is located between the metal layer 112 and the P, N-type bonding pads (110a, 110b).

In some embodiments of the present disclosure, the active emitter layer 105 may be a multiple quantum well (MQW) structure, but not being limited thereto.

In some embodiments of the present disclosure, the vertical cavity surface emitting laser device may further include an ohmic contact layer 109a between the P-type bonding pad 110a and the P-type Bragg reflector layer to serve as an ohmic contact interface, but not being limited thereto.

In some embodiments of the present disclosure, the vertical cavity surface emitting laser device may further include an ohmic contact layer 109b between the N-type bonding pad 110b and the current conductive layer 116 to serve as an ohmic contact interface, but not being limited thereto.

In some embodiments of the present disclosure, the vertical cavity surface emitting laser device may include an anti-reflection layer 114 on surfaces of the metal layer 112 and the through hole 112a, but not being limited thereto.

In some embodiments of the present disclosure, the current conductive layer 116 has a thickness between 1.5 microns and 3 microns, thereby reducing the overall thickness of the laser device, but not being limited thereto.

In some embodiments of the present disclosure, a vertical projection area of the P-type Bragg reflector layer 106 on the semiconductor substrate 102a is smaller than a vertical projection area of the N-type Bragg reflector layer 104 on the semiconductor substrate 102a, but not being limited thereto.

In some embodiments of the present disclosure, the vertical cavity surface emitting laser device further includes an insulation structure 108a passing through the holes in the P-type Bragg reflector layer 106 and the active emitter layer 105, but not being limited thereto.

In some embodiments of the present disclosure, the vertical cavity surface emitting laser device further includes an insulation structure 108b passing through the holes in the P-type Bragg reflector layer 106, the active emitter layer 105, and the N-type Bragg reflector layer 104, but not being limited thereto.

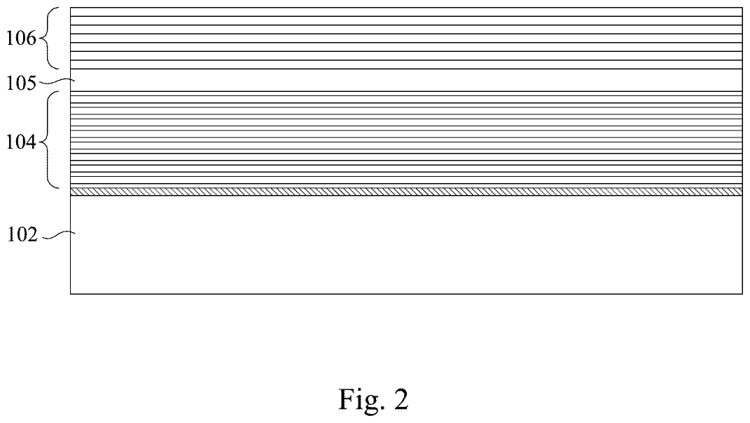

Reference is made to FIGS. 2-13, which illustrate cross-sectional views of a method for manufacturing a vertical cavity surface emitting laser device at various stages in accordance with some embodiments of the present disclosure.

In the step of FIG. 2, a current conductive layer 116, an N-type Bragg reflector layer 104, an active emitter layer 105, and a P-type Bragg reflector layer 106 are sequentially formed on the semiconductor substrate 102.

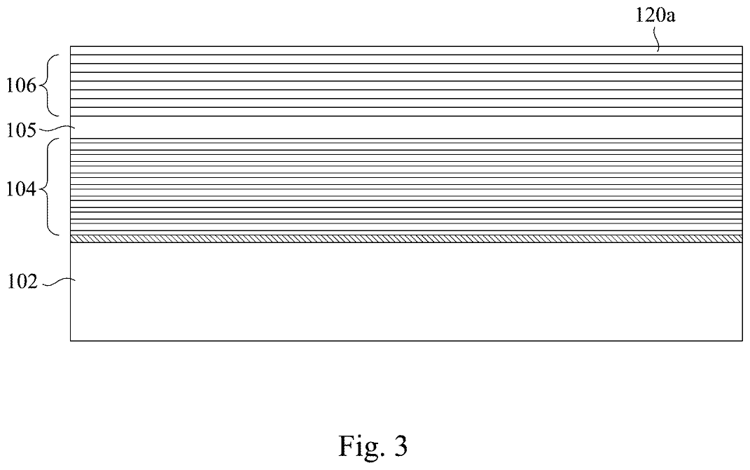

In the step of FIG. 3, a protective layer 120a (e.g., a silicon nitride layer) is formed to cover an upper surface of the P-type Bragg reflector layer 106.

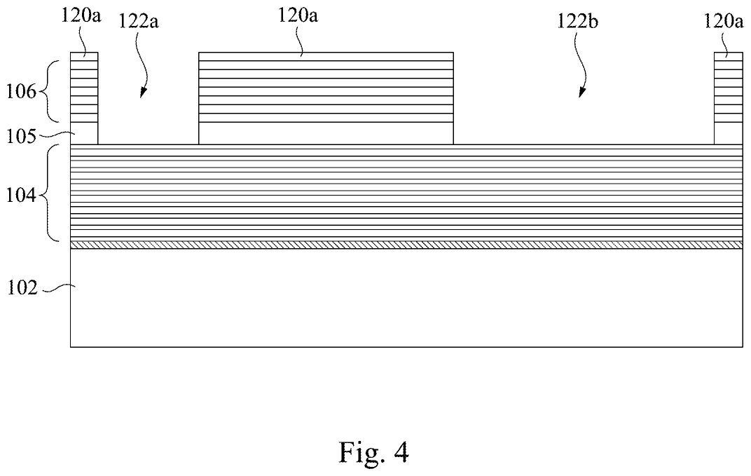

In the step of FIG. 4, the P-type Bragg reflector layer 106 and the active emitter layer 105 are dry-etched to form a through-hole 122a and a through-hole 122b.

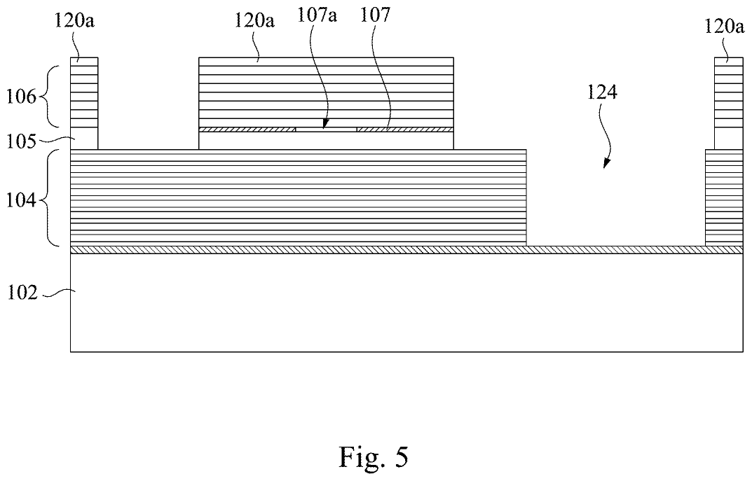

In the step of FIG. 5, the N-type Bragg reflector layer 104 is wet-etched to form a through-hole 124 via the through-hole 122b to expose the current conductive layer 116. By means of an oxidation process on the interface of the active emitter layer 105 and the P-type Bragg reflector layer 106, a current restriction layer 107 is formed to equip with a current restriction hole 107a.

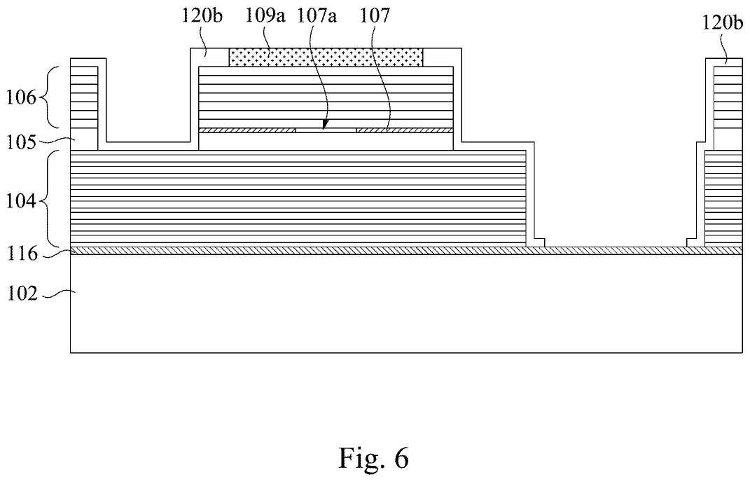

In the step of FIG. 6, a protective layer 120b is formed to cover the through-holes, and an ohmic contact layer 109a is formed on an upper surface of the P-type Bragg reflector layer 106.

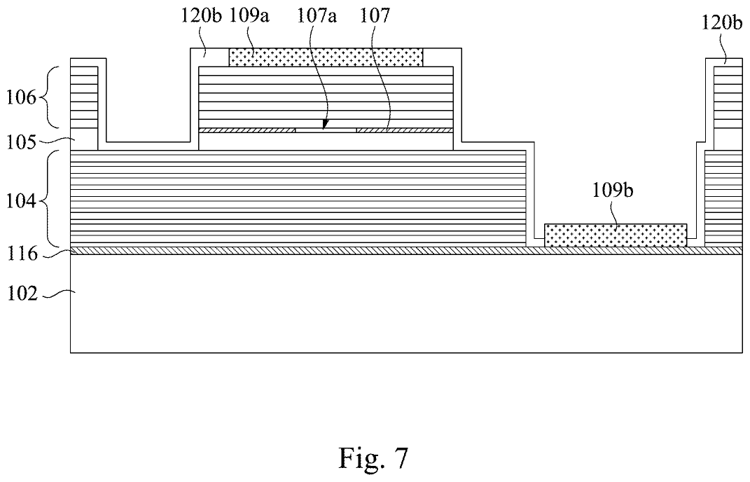

In the step of FIG. 7, an ohmic contact layer 109b is formed on an upper surface of the current conductive layer 116.

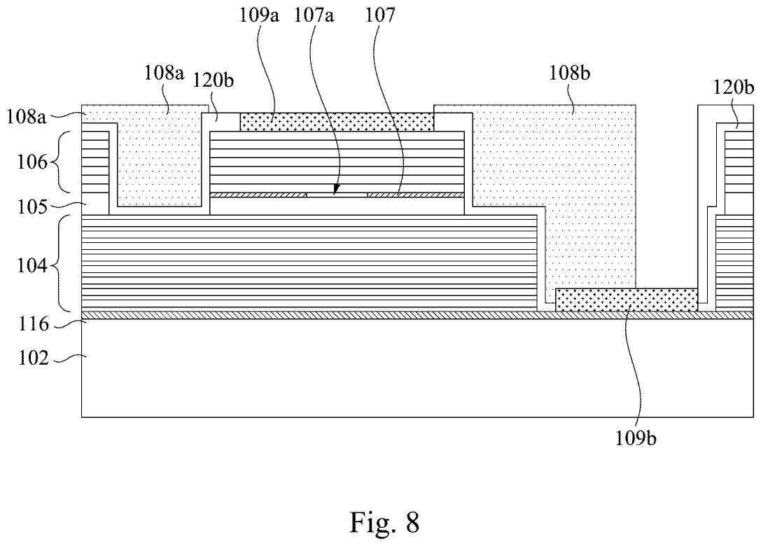

In the step of FIG. 8, the insulation structure 108a and the insulation structure 108b are respectively filled in two through-holes, and an upper surface of a portion of the ohmic contact layer 109b is exposed.

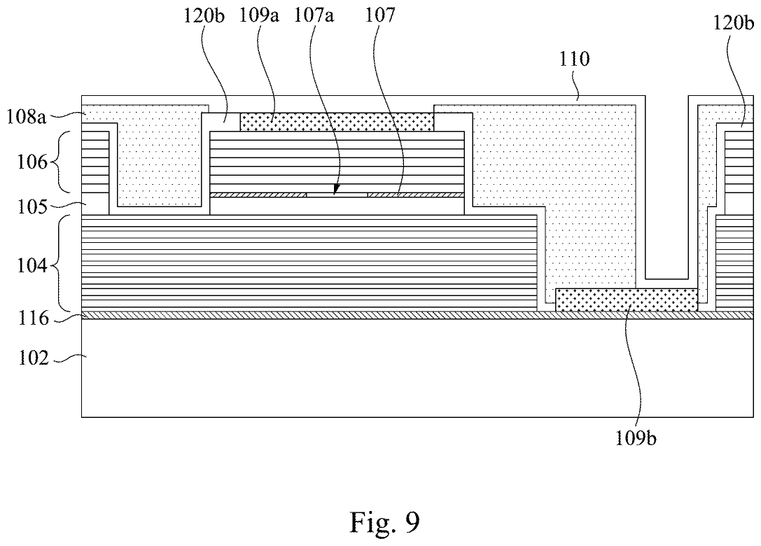

In the step of FIG. 9, a bonding pad seed layer 110 is formed to contact the ohmic contact layer 109a and the ohmic contact layer 109b.

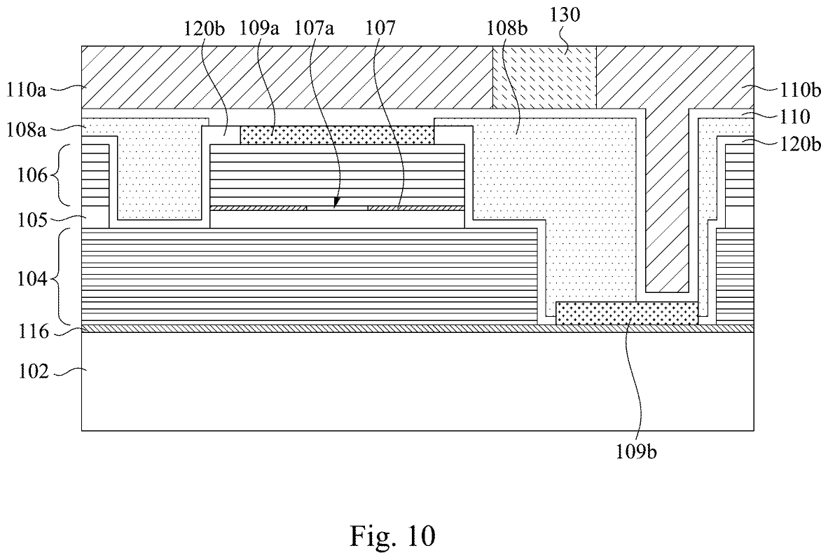

In the step of FIG. 10, an insulating block 130 is first formed, and then a bonding pad seed layer 110 is electroplated on both sides of the insulating block 130 to form a P-type bonding pad 110a and a N-type bonding pads 110b separated from each other.

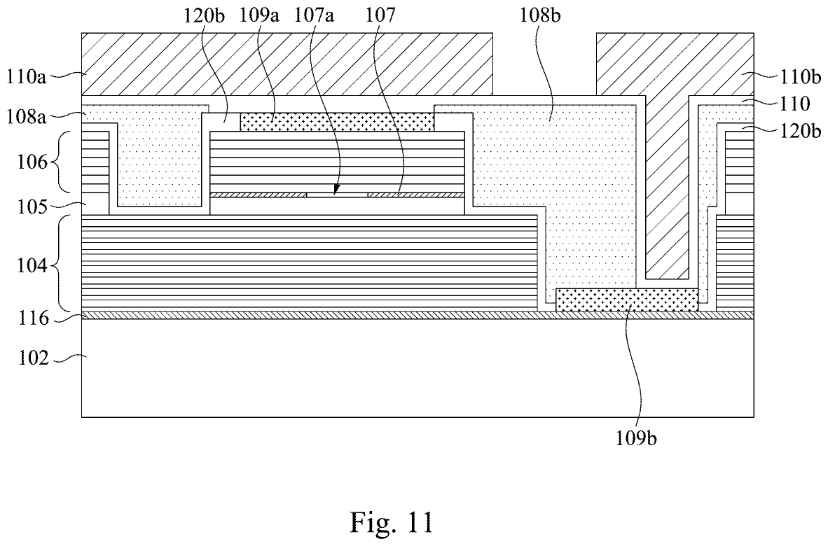

In the step of FIG. 11, the insulating block 130 is removed by an etching step.

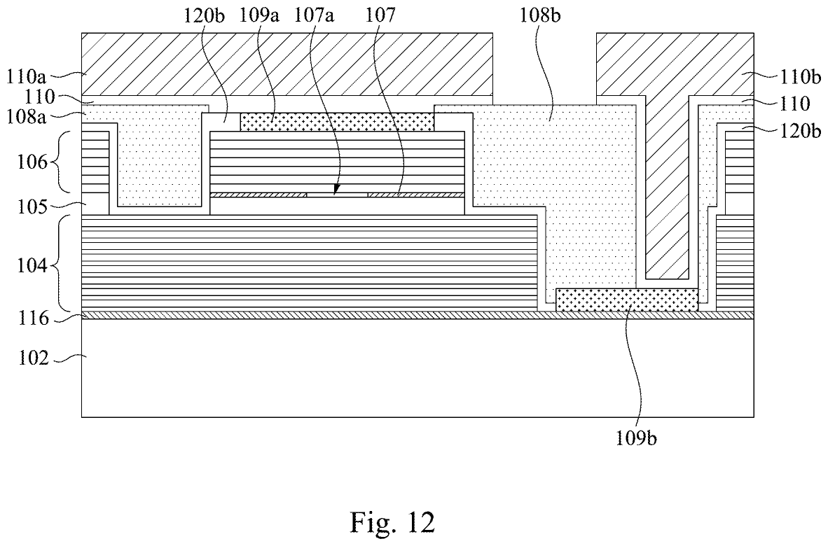

In the step of FIG. 12, a part of the bonding pad seed layer 110 under the insulating block 130 is removed by another etching step, so that the P-type bonding pad 110a and the N-type bonding pad 110b can be insulated from each other. The P-type bonding pad 110a contacts the ohmic contact layer 109a, and an extension portion of the N-type bonding pad 110b has its bottom in ohmic contact with the ohmic contact layer 109b. The current channel is the P-type bonding pad 110a through the ohmic contact layer 109a to the P-type Bragg reflector layer 106 and the active emitter layer 105. The other current channel is the N-type bonding pad 110b through the ohmic contact layer 109b, the current conductive layer 116 to the N-type Bragg reflector layer 104 and the active emitter layer 105.

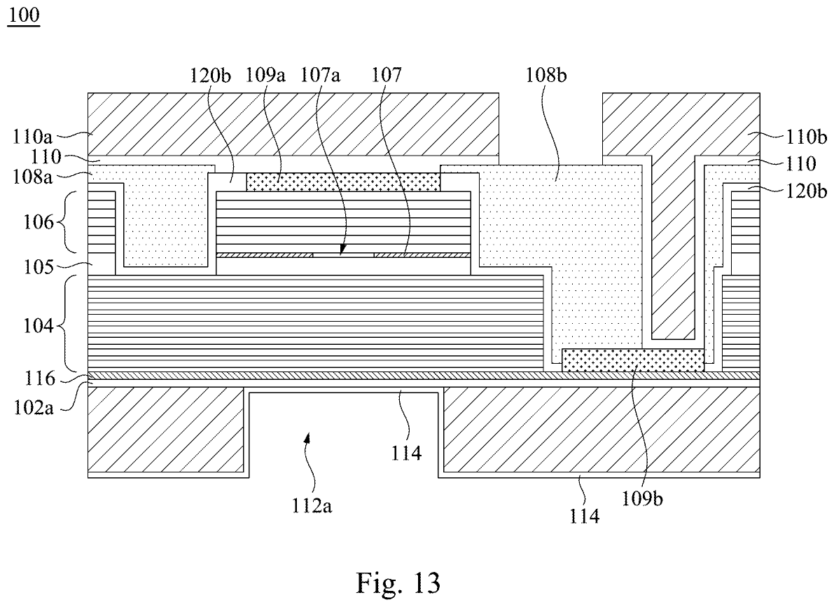

In the step of FIG. 13, the semiconductor substrate 102a is reduced to a thickness between 50 microns and 150 microns, and a metal layer 112 is formed to contact the semiconductor substrate 102a. The metal layer 112 is etched to form a through hole 112a aligned with the restriction hole 107a to serve as a light emitting hole of the laser light. Finally, an anti-reflection layer 114 is formed on surfaces of the metal layer 112 and the through hole 112a.

In summary, the vertical cavity surface emitting laser device of the present invention reduces the thickness of the laser device as a whole by reducing the thickness of the semiconductor substrate down to a range from 50 μm to 150 μm, and the metal layer, the P-type bonding pad and the N-type bonding pad each have a thickness between 20 micrometers and 40 micrometers so as to form a stress relief system, thereby balancing the stress within the layers to prevent warpage.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A vertical cavity surface emitting laser device comprising:
a semiconductor substrate having a thickness ranging from 50 microns to 150 microns;
a current conductive layer disposed on the semiconductor substrate and having a carrier concentration ranging from 3E18 to 5E18;
a N-type Bragg reflector layer disposed in contact with the current conductive layer;
a P-type Bragg reflector layer disposed above the N-type Bragg reflector layer;
an active emitter layer disposed between the P-type Bragg reflector layer and the N-type Bragg reflector layer;
a current restriction layer disposed between the active emitter layer and the P-type Bragg reflector layer, wherein the current restriction layer has a current restriction hole;
a metal layer disposed in contact with the semiconductor substrate, wherein the semiconductor substrate is disposed between the N-type Bragg reflector layer and the metal layer, wherein the metal layer has a through hole aligned with the current restriction hole;
a P-type bonding pad disposed in ohmic contact with the P-type Bragg reflector layer, and a portion of the P-type bonding pad is aligned with the current restriction hole and the through hole; and
a N-type bonding pad disposed in ohmic contact with the current conductive layer, and electrically separated from the P-type bonding pad, wherein the P-type bonding pad and the N-type bonding pad are disposed at a same side of the semiconductor substrate, each of the metal layer, the P-type bonding pad and the N-type bonding pad has a thickness ranging from 20 microns to 40 microns so as to achieve a stress relief system.

2. The vertical cavity surface emitting laser device of claim 1, wherein the semiconductor substrate is disposed between the metal layer and the P-type, N-type bonding pads.

3. The vertical cavity surface emitting laser device of claim 1, wherein the active emitter layer comprises quantum wells.

4. The vertical cavity surface emitting laser device of claim 1, further comprising an ohmic contact layer disposed between the P-type bonding pad and the P-type Bragg reflector layer.

5. The vertical cavity surface emitting laser device of claim 1, further comprising an ohmic contact layer disposed between the N-type bonding pad and the current conductive layer.

6. The vertical cavity surface emitting laser device of claim 1, further comprising an anti-reflection layer disposed over a surface of the metal layer and the through hole.

7. The vertical cavity surface emitting laser device of claim 1, wherein the current conductive layer has a thickness ranging from 1.5 microns to 3 microns.

8. The vertical cavity surface emitting laser device of claim 1, wherein a projection area of the P-type Bragg reflector layer on the semiconductor substrate is smaller than a projection area of the N-type Bragg reflector layer on the semiconductor substrate.

9. The vertical cavity surface emitting laser device of claim 1, further comprising an insulation structure penetrating through the P-type Bragg reflector layer and the active emitter layer.

10. The vertical cavity surface emitting laser device of claim 1, further comprising an insulation structure penetrating through the P-type Bragg reflector layer, the active emitter layer and the N-type Bragg reflector layer.
